(19) United States
(12) Patent Application Publication
(10) Pub. No.: US 2025/0279796 A1
(43) Pub. Date: Sep. 4, 2025

(54) Linearization Technique for PAM-4 CMOS Electrical-to-Optical Interface

(71) Applicant: Ayar Labs, Inc., San Jose, CA (US)

(72) Inventors: Woorham Bae, Santa Clara, CA (US); Pavan Bhargava, Berkeley, CA (US)

(21) Appl. No.: 19/066,850

(22) Filed: Feb. 28, 2025

Related U.S. Application Data
(60) Provisional application No. 63/560,687, filed on Mar. 2, 2024.

(51) Int. Cl. H04B 1/04; H03F 1/32

(52) U.S. Cl. CPC H04B 1/0483; H03F 1/3276; H03F 2200/339; H04B 2001/0425

(57) ABSTRACT

A linearity control circuit includes first and second input terminals. A first differential amplifier has a first input connected to the second input terminal and a second input connected to the first input terminal. Inputs of a first weighting circuit are respectively connected to outputs of the first differential amplifier. A second differential amplifier has a first input connected to the first input terminal and a second input connected to the second input terminal. Inputs of a second weighting circuit are respectively connected to outputs of the second differential amplifier. A summing device has a first input connected to an output of the first weighting circuit and a second input connected to an output of the second weighting circuit. An output of the summing device is an output of the linearity control circuit.

### CROSS-REFERENCE TO RELATED APPLICATIONS

This application claims priority under 35 U.S.C. 119 (e) to U.S. Provisional Patent Application No. 63/560,687, filed on Mar. 2, 2024, the disclosure of which is incorporated herein by reference in its entirety for all purposes.

### BACKGROUND OF THE INVENTION

Optical data communication systems operate by modulating laser light to encode digital data patterns within optical signals. The modulated laser light is transmitted through an optical data network from a sending node to a receiving node. The modulated laser light having arrived at the receiving node is de-modulated to obtain the original digital data patterns from the optical signals. The transmission of light through the optical data network includes transmission of light through optical fibers and transmission of light between optical fibers and photonic integrated circuits. In some embodiments, a photodiode is used to detect light of an optical data signal and convert the detected light into a photocurrent that can be processed through electrical circuitry to demodulate the optical data signal to obtain the original digital data pattern from the optical data signal. It is within this context that the present invention arises.

### SUMMARY OF THE INVENTION

In an example embodiment, a linearity control circuit is disclosed. The linearity control circuit includes a first input terminal and a second input terminal. The linearity control circuit also includes a first differential amplifier that has a first input connected to the second input terminal and a second input connected to the first input terminal. The first differential amplifier has a first output and a second output. The linearity control circuit also includes a first weighting circuit that has a first input connected to the first output of the first differential amplifier. The first weighting circuit has a second input connected to the second output of the first differential amplifier. The first weighting circuit has a first output and a second output. The first weighting circuit is configured to scale signals received at each of first and second inputs of the first weighting circuit by a first scaling coefficient to generate respective signals at the first and second outputs of the first weighting circuit. The linearity control circuit also includes a second differential amplifier that has a first input connected to the first input terminal and a second input connected to the second input terminal. The second differential amplifier has a first output and a second output. The linearity control circuit also includes a second weighting circuit that has a first input connected to the first output of the second differential amplifier. The second weighting circuit has a second input connected to the second output of the second differential amplifier. The second weighting circuit has a first output and a second output. The second weighting circuit is configured to scale signals received at each of first and second inputs of the second weighting circuit by a second scaling coefficient to generate respective signals at the first and second outputs of the second weighting circuit. The linearity control circuit also includes a first summing device that has a first input connected to the first output of the first weighting circuit and a second input connected to the first output of the second weighting circuit. The first summing device has an output that is a first output of the linearity control circuit. The linearity control circuit also includes a second summing device that has a first input connected to the second output of the first weighting circuit. The second summing device also has a second input connected to the second output of the second weighting device. The second summing device has an output that is a second output of the linearity control circuit.

In an example embodiment, a method is disclosed for operating a linearity control circuit. The method includes conveying a negative version of a given input signal to a negative input terminal of a first differential amplifier. The method also includes conveying a positive version of the given input signal to a positive input terminal of the first differential amplifier. The method also includes operating the first differential amplifier to output a first differential signal. The method also includes conveying the first differential signal as input to a first weighting circuit. The method also includes operating the first weighting circuit to output a first scaled signal corresponding to the first differential signal scaled by a first scaling coefficient. The method also includes conveying the negative version of the given input signal to a positive input terminal of a second differential amplifier. The method also includes conveying the positive version of the given input signal to a negative input terminal of the second differential amplifier. The method also includes operating the second differential amplifier to output a second differential signal. The method also includes conveying the second differential signal as input to a second weighting circuit. The method also includes operating the second weighting circuit to output a second scaled signal corresponding to the second differential signal scaled by a second scaling coefficient. The method also includes summing a positive version of the first scaled signal and a negative version of the second scaled signal to generate a first output signal of the linearity control circuit. The method also includes summing a negative version of the first scaled signal and a positive version of the second scaled signal to generate a second output signal of the linearity control circuit.

### BRIEF DESCRIPTION OF THE DRAWINGS

FIG. 1A shows a simplified block diagram of a CMOS repeater/amplifier device implemented to reduce electrical signal delay along an electrical signal conveyance pathway, in accordance with some embodiments.

FIG. 1B shows a simplified block diagram of a CMOS repeater/amplifier device implemented to reduce electrical signal delay along an electrical signal conveyance pathway that is used to drive optical modulation, in accordance with some embodiments.

FIG. 2 shows a first transfer gain diagram (top-left plot of Vout versus Vin) of a CMOS repeater/amplifier device having corresponding acceptable linearity in PAM-4 signal transmission, along with a second transfer gain diagram (top-right plot of Vout versus Vin) of a CMOS repeater/amplifier device with unacceptable linearity in PAM-4 signal transmission, in accordance with some embodiments.

FIG. 3A shows an E-E repeater/amplifier configuration that implements a linearity control circuit, in accordance with some embodiments.

FIG. 3B shows an E-O repeater/amplifier configuration that implements the linearity control circuit, in accordance with some embodiments.

FIG. 3C shows a circuit diagram of the linearity control circuit, in accordance with some embodiments.

FIG. 4A shows an example implementation of the first summing device, where the first summing device is configured to provide for current summing, in accordance with some embodiments.

FIG. 4B shows an example implementation of the second summing device, where the second summing device is configured to provide for current summing, in accordance with some embodiments.

FIG. 4C shows an example implementation of the first summing device, where the first summing device is configured to provide for voltage summing, in accordance with some embodiments.

FIG. 4D shows an example implementation of the second summing device, where the second summing device is configured to provide for voltage summing, in accordance with some embodiments.

FIG. 5A shows the operating principle of the linearity control circuit for a low coefficient (k) value, in accordance with some embodiments.

FIG. 5B shows the operating principle of the linearity control circuit for a high coefficient (k) value, in accordance with some embodiments.

FIG. 6 shows how the linearity control circuit operates to pre-distort the PAM-4 signal so as to tolerate/mitigate the linearity degradation that is caused by the CMOS repeater/amplifier, in accordance with some embodiments.

FIG. 7 shows a flowchart of a method for operating a linearity control circuit, in accordance with some embodiments.

### DETAILED DESCRIPTION

In the following description, numerous specific details are set forth in order to provide an understanding of the embodiments disclosed herein. It will be apparent, however, to one skilled in the art that the embodiments disclosed herein may be practiced without some or all of these specific details. In other instances, well known process operations have not been described in detail in order not to unnecessarily obscure the disclosed embodiments.

The embodiments disclosed herein relate to optical data communication. Optical data communication systems operate by modulating laser light to encode digital data patterns within optical data signals. In some embodiments, a ring modulator is used to modulate continuous wave laser light to generate the modulated laser light that conveys the encoding of digital data patterns. In some embodiments, the ring modulator is positioned within an evanescent optically coupling distance from a bus optical waveguide and operates to modulate light that is propagating through the bus optical waveguide. The modulated laser light is transmitted through an optical data network from a sending node to a receiving node. The modulated laser light having arrived at the receiving node is de-modulated to obtain the original digital data patterns from the optical data signals. The transmission of light through the optical data network includes transmission of light through optical fibers and transmission of light between optical fibers and photonic integrated circuits. In some embodiments, a photodiode is used to detect light of an optical data signal and convert the detected light into a photocurrent that can be processed through electrical circuitry to demodulate the optical data signal to obtain the original digital data pattern from the optical data signal.

Optical cavities are used in a variety of applications in optical data communication systems, in various devices, such as lasers, optical modulators, optical splitters, optical routers, optical switches, and optical detectors, among others. In various applications and configurations, optical cavities may show strong wavelength selectivity. For this reason, optical cavities are useful in systems that rely on multiple optical data signals transmitting information at different wavelengths. In some embodiments, optical cavities are configured as ring resonators and/or disk resonators to enable applications in which light that is coupled from an input optical waveguide into the optical cavity of the ring/disk resonator is either efficiently routed to a separate output optical waveguide, or absorbed within the optical cavity of the ring/disk resonator at specific wavelengths. Also, optical cavities, such as ring/disk resonators, are useful in sensing applications, such as in biological or chemical sensing applications in which a high concentration of optical power is needed in a small area.

In various embodiments, electrical data signals are used to drive optical modulation within an optical cavity of a ring/disc modulator. In various embodiments, electrical signal repeater/amplifier devices, such as CMOS (complementary metal oxide semiconductor) repeater/amplifier devices, are implemented within integrated circuits to mitigate/reduce electrical signal delay along an electrical signal conveyance pathway that extends from an origination point of the electrical signal to a destination point of the electrical signal. Electrical repeater/amplifier devices, such as CMOS repeater/amplifier devices, play an important role in transmitting ultra-high-speed data through electrical wires for either within chip (inter-chip) data communication and/or between chips (chip-to-chip) data communication. In some embodiments, particularly in optical data communication devices and/or systems, an electrical data signal that is used to drive optical modulation within a ring/disc modulator has to be sent along a electrical signal conveyance pathway from an origination point of the electrical data signal to the optical cavity that is used to modulate a beam of continuous wave laser light to transfer the digital data present within the electrical data signal into an optical data signal within the optical domain. In these embodiments, one or more CMOS repeater/amplifier devices are implemented along the electrical signal conveyance pathway to mitigate/reduce delay and/or mitigate/reduce signal loss associated with transmission of the electrical data signal from its origination point to the optical cavity of the ring/disc modulator.

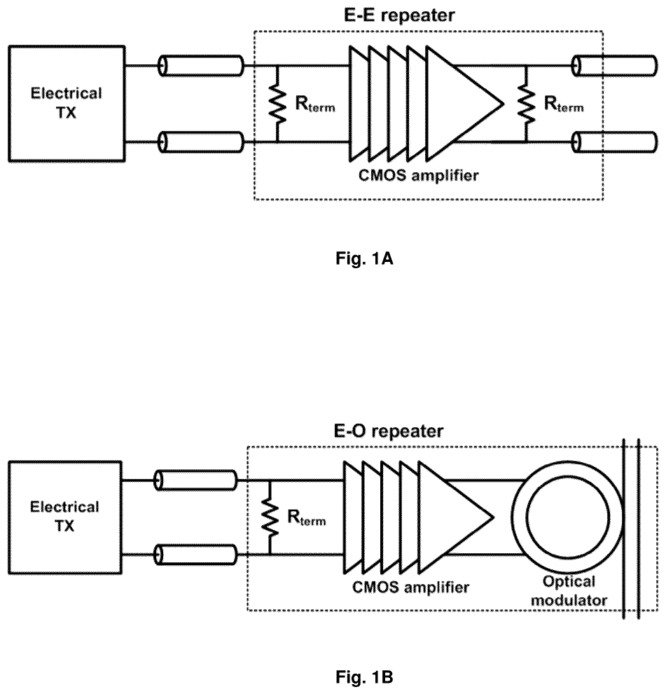

FIG. 1A shows a simplified block diagram of a CMOS repeater/amplifier device implemented to reduce electrical signal delay along an electrical signal conveyance pathway, in accordance with some embodiments. The CMOS repeater/amplifier implementation of FIG. 1A is referred to as an Electrical-to-Electrical (E-E) repeater/amplifier configuration. FIG. 1B shows a simplified block diagram of a CMOS repeater/amplifier device implemented to reduce electrical signal delay along an electrical signal conveyance pathway that is used to drive optical modulation, in accordance with some embodiments. The CMOS repeater/amplifier implementation of FIG. 1B is referred to as an Electrical-to-Optical (E-O) repeater/amplifier configuration. Because frequency-dependent data communication signal channel loss increases exponentially with the length of an electrical wire, inserting electrical signal repeaters/amplifiers, e.g., CMOS repeaters/amplifiers, breaks a high-loss wire into multiple low-loss wires and significantly improves the signal integrity, while also reducing the cumulative signal transmission delay along the electrical signal conveyance pathway. An electrical signal repeater/amplifier device, e.g., CMOS repeater/amplifier, receives a high-speed electrical signal through an electrical link and reconditions the electrical signal through a repeater/amplifier chain (which may include one or more equalization circuits) before transmitting the reconditioned electrical signal it to another electrical link.

An E-O interface provides for transmission of ultra-high-speed optical data communication signals through optical fiber. The E-O interface receives a high-speed electrical signal from a computing unit through an electrical link and amplifies the high-speed electrical signal to drive an optical device, such as an optical modulator or another type of electro-optical device. In general, electrical signal distortion should be minimized in the repeater/amplification chains of signal repeater/amplifier devices so as to conserve the quality of the original electrical signal.

In some embodiments, a data communication system implements an ultra-high-speed electrical link standard, such as the four-level pulse-amplitude modulation (PAM-4) signaling standard which transmits two bits per symbol period, in order to overcome the frequency-dependent data communication signal channel loss. In contrast to binary non-return-to-zero (NRZ) signaling, PAM-4 signaling is sensitive to the non-linearity-induced loss caused by the repeater/amplifier chain, e.g., caused by the CMOS repeater/amplifier device(s) along the electrical signal conveyance pathway. In PAM-4 signal transmission, linearity measures the variance in amplitude separation between the four different PAM-4 pulse amplitude levels, i.e., the variance between V₁₋₀, V₂₋₁, V₃₋₂, where V₀, V₁, V₂, and V₃ are the four different PAM-4 pulse amplitude levels, and where V₁₋₀ is V₁-V₀, and where V₂₋₁ is V₂-V₁, and where V₃₋₂ is V₃-V₂. Maintaining acceptable linearity in PAM-4 signal transmission is a challenge with implementation of CMOS repeaters/amplifiers along the electrical signal conveyance pathway, because many electrical interfaces require a high voltage swing output, whereas CMOS repeater/amplifier circuits do not retain linearity with such a high voltage swing signal. For the electrical-to-optical (E-O) repeaters/amplifiers, such as shown in the configuration of FIG. 1B, the linearity issue is even more challenging because a very high voltage swing electrical signal is required to drive the optical modulator. More specifically, the transfer gain of a CMOS repeater/amplifier circuit is higher when the voltage amplitude of the input signal is small. As a result, after passing through the CMOS repeater/amplifier chain, the top and bottom eyes of the PAM-4 signal become smaller than the middle eye and correspondingly constrain the achievable bit-error-rate (BER).

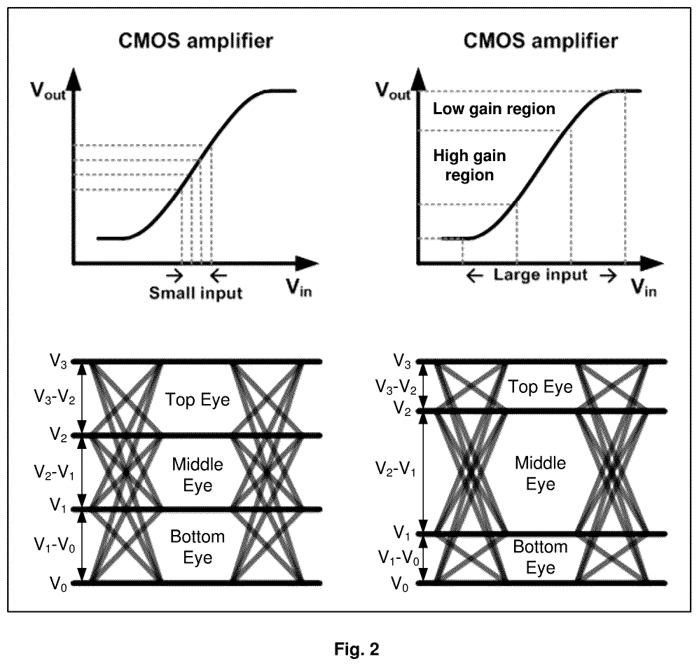

FIG. 2 shows a first transfer gain diagram (top-left plot of Vout versus Vin) of a CMOS repeater/amplifier device having corresponding acceptable linearity in PAM-4 signal transmission, along with a second transfer gain diagram (top-right plot of Vout versus Vin) of a CMOS repeater/amplifier device with unacceptable linearity in PAM-4 signal transmission, in accordance with some embodiments. FIG. 2 also shows the four PAM-4 pulse amplitude levels V₀, V₁, V₂, and V₃ (bottom-left diagram) for the first transfer gain diagram (top-left plot of Vout versus Vin) of the CMOS repeater/amplifier device having corresponding acceptable linearity in PAM-4 signal transmission, which shows small variance in amplitude separation between the four PAM-4 pulse amplitude levels. The sizes of the top eye, middle eye, and bottom eye are substantially equal to each other in the bottom-left diagram of FIG. 2, which is indicative of linearity in PAM-4 signal transmission. FIG. 2 also shows the four PAM-4 pulse amplitude levels V₀, V₁, V₂, and V₃ (bottom-right diagram) for the second transfer gain diagram (top-right plot of Vout versus Vin) of the CMOS repeater/amplifier device having unacceptable linearity in PAM-4 signal transmission, which shows large variance in amplitude separation between the four PAM-4 pulse amplitude levels. The size of the middle eye is larger than the sizes of the top and bottom eyes in the bottom-right diagram of FIG. 2, which is indicative of non-linearity in PAM-4 signal transmission.

Various embodiments are disclosed herein for a compact and energy-efficient linearity-tuning scheme for PAM-4 signal transmission in conjunction with implementation of CMOS repeater/amplifier devices, which provides for full equalization of the four pulse amplitude levels in PAM-4 signal transmission. In general, the linearity of the CMOS repeater/amplifier gets worse as the swing of the PAM-4 input signal gets higher. Because many electrical interface standards, e.g., PAM-4 E-O interface standards, are required to handle high-swing input signals, maintaining acceptable linearity (providing linearity mitigation and/or correction) is very important. As discussed above, FIG. 2 shows the transfer gain diagram (Vout versus Vin curve) of the CMOS repeater/amplifier and how a high-swing of the PAM-4 input signal is distorted by the CMOS repeater/amplifier. When the electrical input signal amplitude is large, the output of the CMOS repeater/amplifier saturates for various reasons, such as because the electrical input signal amplitude reaches to the bias rails and/or the transistor of the CMOS repeater/amplifier enters the triode region. Because such linearity distortion is very sensitive to process, voltage, and temperature (PVT) variations, in addition to having the high-swing of the PAM-4 input signal, the linearity distortion caused by the CMOS repeater/amplifier can rarely be resolved just by optimizing the CMOS repeater/amplifier design.

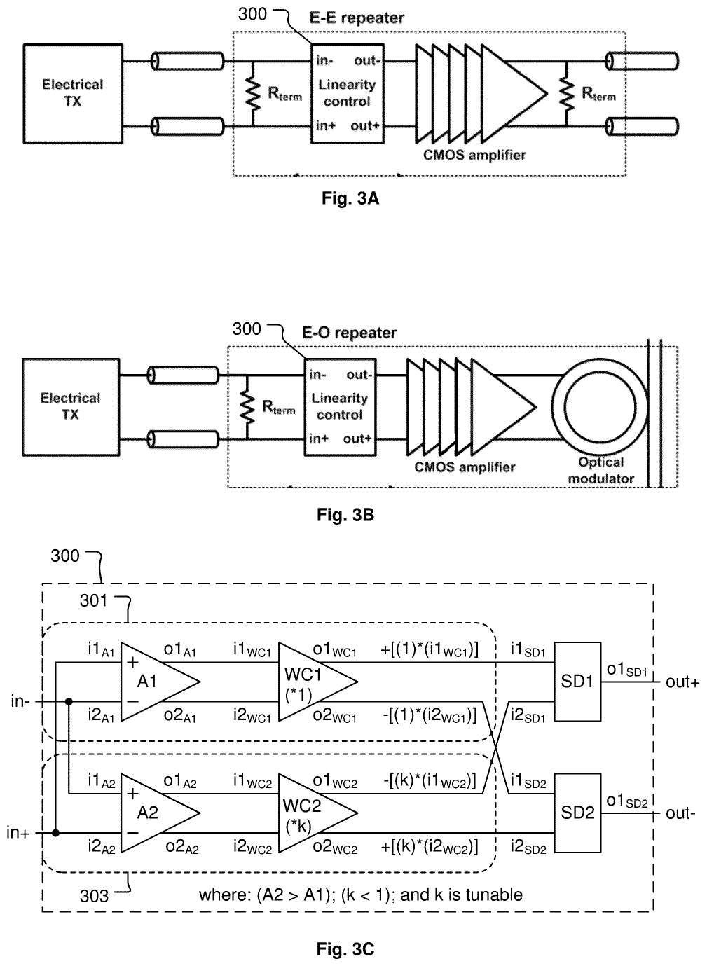

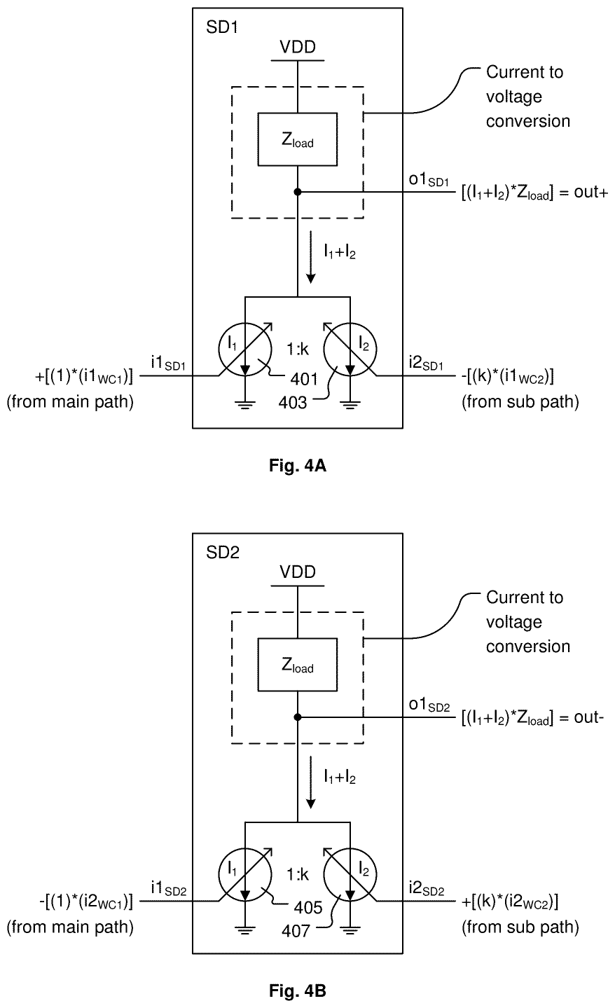

FIG. 3A shows an E-E repeater/amplifier configuration that implements a linearity control circuit 300, in accordance with some embodiments. FIG. 3B shows an E-O repeater/amplifier configuration that implements the linearity control circuit 300, in accordance with some embodiments. FIG. 3C shows a circuit diagram of the linearity control circuit 300, in accordance with some embodiments. For a given input (in−, in+), the linearity control circuit 300 includes two amplifier pathways, namely a “main path” 301 and a “sub path” 303. The main path 301 includes a first differential amplifier A1 and a first weighting circuit WC1. The sub path 303 includes a second differential amplifier A2 and a second weighting circuit WC2. A negative version of the input signal (in−) is transmitted to both a second input (i2_{A1}) (negative input) of the first differential amplifier A1 and a first input (i1_{A2}) (positive input) of the second differential amplifier A2. A positive version of the input signal (in+) is transmitted to both a first input (i1_{A1}) (positive input) of the first differential amplifier A1 and a second input (i2_{A2}) (negative input) of the second differential amplifier A2. In this manner, the sub path 303 has a flipped polarity relative to the main path 301. A first output (o1_{A1}) of the first differential amplifier A1 of the main path 301 is connected to a first input (i1_{WC1}) of the first weighting circuit WC1. A second output (o2_{A1}) of the first differential amplifier A1 of the main path 301 is connected to a second input (i2_{WC1}) of the first weighting circuit WC1. A second output (o2_{A1}) of the first differential amplifier A1 of the main path 301 is connected to a second input (i2_{WC1}) of the first weighting circuit WC1. With regard to the sub path 303, a first output (o1_{A2}) of the second differential amplifier A2 is connected to the a first input (i1_{WC2}) of the second weighting circuit WC2. Also, a second output (o2_{A2}) of the second differential amplifier A2 is connected to the a second input (i2_{WC2}) of the second weighting circuit WC2.

A first output (o1_{WC1}) of the first weighting circuit WC1 of the main path 301 is connected to a first input (i1_{SD1}) of a first summing device SD1. Also, the first output (o1_{WC2}) of the second weighting circuit WC2 of the sub path 303 is connected to a second input (i2_{SD1}) of the first summing device SD1. An output (o1_{SD1}) of the first summing device SD1 is a first output (out+) of the linearity control circuit 300. A second output (o2_{WC1}) of the first weighting circuit WC1 of the main path 301 is connected to a first input (i1_{SD2}) of a second summing device SD2. Also, a second output (o2_{WC2}) of the second weighting circuit WC2 of the sub path 303 is connected to a second input (i2_{SD2}) of the second summing device SD2. An output (o1_{SD2}) of the second summing device SD2 is a second output (out−) of the linearity control circuit 300.

The first summing device SD1 and the second summing device SD2 have the same configuration. In some embodiments, the first weighting circuit WC1 is configured to apply a weighting coefficient of one. The output signal transmitted from the first output (o1_{WC1}) of the first weighting circuit WC1 to the first input (i1_{SD1}) of the first summing device SD1 is the input signal received at the first input (i1_{WC1}) of the first weighting circuit WC1 multiplied by positive one (+1), i.e., + [(1)*(i1_{WC1})]. Similarly, the output signal transmitted from the second output (o2_{WC1}) of the first weighting circuit WC1 to the first input (i1_{SD2}) of the second summing device SD2 is the input signal received at the second input (i2_{WC1}) of the first weighting circuit WC1 multiplied by negative one (−1), i.e., −[(1)*(i2_{WC1})]. The second weighting circuit WC2 is configured to apply a weighting coefficient of k, where k is less than one, and where k is tunable. The output signal transmitted from the first output (o1_{WC2}) of the second weighting circuit WC2 to the second input (i2_{SD1}) of the first summing device SD1 is the input signal received at the first input (i1_{WC2}) of the second weighting circuit WC2 multiplied by negative k (−k), i.e., −[(k)*(i1_{WC2})]. Similarly, the output signal transmitted from the second output (o2_{WC2}) of the second weighting circuit WC2 to the second input (i2_{SD2}) of the second summing device SD2 is the input signal received at the second input (i2_{WC2}) of the second weighting circuit WC2 multiplied by positive k (+k), i.e., + [(k)*(i2_{WC2})]. In this manner, the two input signals at the second summing device SD2 are substantially equal in magnitude but reversed in polarity relative to the two input signals at the first summing device SD1. Therefore, the output signal (o1_{SD1}) from the first summing device SD1 has a magnitude that is substantially equal to a magnitude of the output signal (o1_{SD2}) from the second summing device SD2. Also, the output signal (o1_{SD1}) from the first summing device SD1 has a polarity that is opposite of a polarity of the output signal (o1_{SD2}) from the second summing device SD2. Correspondingly, the first output (out+) of the linearity control circuit 300 has a magnitude that is substantially equal to a magnitude of the second output (out−) of the linearity control circuit 300. Also, the first output (out+) of the linearity control circuit 300 has a polarity that is opposite of a polarity of the second output (out−) of the linearity control circuit 300. In various embodiments, each of the first weighting circuit WC1 and the second weighting circuit WC2 is implemented as one or more of an operational amplifier, an operational transconductance amplifier, a differential amplifier, and a differential transconductance amplifier.

The second differential amplifier A2 of the sub path 303 has a higher gain than the first differential amplifier A1 of the main path 301, i.e., (A2>A1). The gain of the second weighting circuit WC2 is scaled relative to the gain of the first weighting circuit WC1 by the coefficient (k). In this manner, the coefficient (k) is used to adjust the relative weight of the sub path 303 relative to the main path 301. Because of the flipped polarity of the sub path 303 relative to the main path 301, the first summing device SD1 and the second summing device SD2 effectively subtract the differential voltage at the output of the second differential amplifier A2 of the sub path 303, as scaled by the coefficient (k), from the differential voltage at the output of the first differential amplifier A1 of the main path 301. Therefore, due to the subtraction of the scaled voltage of the sub path 303 from the voltage of the main path 301, the overall gain provided by the linearity control circuit 300 is equal to the gain of the main path 301 as reduced by the gain of the sub path 303. However, the subtraction of the sub path 303 gain from the main path 301 gain only happens when the sub path 303 does not saturate, which is around the common mode (center) voltage. More specifically, with a high-swing input signal (in−, in+) that causes the sub path 303 to saturate, the gain of the main path 301 is not reduced by the gain of the sub path 303, and the overall gain of the linearity control circuit 300 is substantially equal to the gain of the main path 301. However, with an input signal (in−, in+) swing that does not cause the sub path 303 to saturate, the gain of the main path 301 is reduced by the gain of the sub path 303, and the overall gain of the linearity control circuit 300 is substantially equal to the gain of the main path 301 minus the gain of the sub path 303. Therefore, the linearity control circuit 300 reduces the gain around the common mode (center) voltage which is relevant to the center eye (middle eye) of the PAM-4 signal transmission, while maintaining the same gain for the top eye and bottom eye of the PAM-4 signal transmission. The amount of the gain reduction around the common mode (center) voltage that is provided by the linearity control circuit 300 is proportional to the coefficient (k). Therefore, the coefficient (k) can be set as needed to equalize the top, middle, and bottom eyes of the PAM-4 signal transmission, and even pre-distort one or more of the top, middle, and bottom eyes of the PAM-4 signal transmission to tolerate/mitigate the linearity degradation that occurs through the CMOS repeater/amplifier chains.

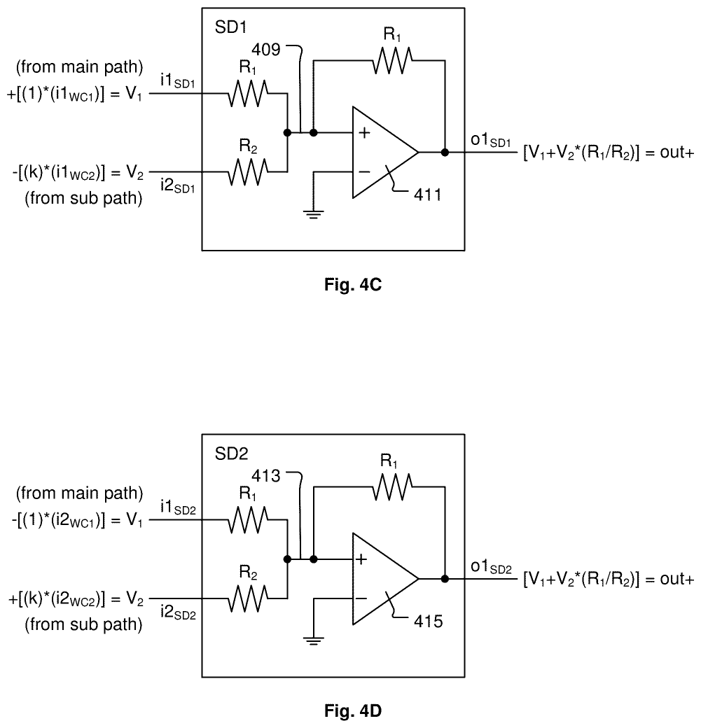

FIG. 4A shows an example implementation of the first summing device SD1, where the first summing device SD1 is configured to provide for current summing, in accordance with some embodiments. FIG. 4B shows an example implementation of the second summing device SD2, where the second summing device SD2 is configured to provide for current summing, in accordance with some embodiments. The first summing device SD1 and the second summing device SD2 of FIGS. 4A and 4B, respectively, are used in conjunction with each other.

With regard to FIG. 4A, the first summing device SD1 includes a first variable current source 401 configured to generate a first current I1 in accordance with a control signal that is received at the first input (i1_{SD1}) of the first summing device SD1. The first summing device SD1 also includes a second variable current source 403 configured to generate a second current I2 in accordance with a control signal that is received at the second input (i2_{SD1}) of the first summing device SD1. The first variable current source 401 and the second variable current source 403 are configured to generate the first current I1 and the second current I2, respectively, at the output (o1_{SD1}) of the first summing device SD1. Also, to provide for conversion of the first current I1 and second current I2 to a voltage, the output (o1_{SD1}) of the first summing device SD1 is connected through a load to a power supply VDD, where the load has an impedance Z_{load}. In this manner, the voltage at the output (o1_{SD1}) of the first summing device SD1 is equal to [(I1+I2)*Z_{load}].

With regard to FIG. 4B, the second summing device SD2 includes a first variable current source 405 configured to generate a first current I1 in accordance with a control signal that is received at the first input (i1_{SD2}) of the second summing device SD2. The second summing device SD2 also includes a second variable current source 407 configured to generate a second current I2 in accordance with a control signal that is received at the second input (i2_{SD2}) of the second summing device SD2. The first variable current source 405 and the second variable current source 407 are configured to generate the first current I1 and the second current I2, respectively, at the output (o1_{SD2}) of the second summing device SD2. Also, to provide for conversion of the first current I1 and second current I2 to a voltage, the output (o1_{SD2}) of the second summing device SD2 is connected through a load to a power supply VDD, where the load has an impedance Z_{load}. In this manner, the voltage at the output (o1_{SD2}) of the second summing device SD2 is equal to [(I1+I2)*Z_{load}].

FIG. 4C shows an example implementation of the first summing device SD1, where the first summing device SD1 is configured to provide for voltage summing, in accordance with some embodiments. FIG. 4D shows an example implementation of the second summing device SD2, where the second summing device SD2 is configured to provide for voltage summing, in accordance with some embodiments. The first summing device SD1 and the second summing device SD2 of FIGS. 4C and 4D, respectively, are used in conjunction with each other.

With regard to FIG. 4C, the first input (i1_{SD1}) of the first summing device SD1 is connected to a node 409 through a connection having a resistance R1. Also, the second input (i2_{SD1}) of the first summing device SD1 is connected to the node 409 through a connection having a resistance R2. The node 409 is connected to a positive input (+) of an amplifier 411. A negative input (−) of the amplifier 411 is connected to a reference ground potential. An output of the amplifier 411 is connected to the output (o1_{SD1}) of the first summing device SD1. Also, the node 409 is connected to the output (o1_{SD1}) of the first summing device SD1 through a connection that also has the resistance R1 and that bypasses the amplifier 411. In this manner, the voltage at the output (o1_{SD1}) of the first summing device SD1 is equal to a sum of the voltage V1 at the first input (i1_{SD1}) of the first summing device SD1 and a product of the voltage V2 at the second input (i2_{SD1}) of the first summing device SD1 and a ratio of the resistance R1 divided by the resistance R2, i.e., [V1+V2*(R1/R2)]=voltage at output o1_{SD1}. With regard to FIG. 4D, the first input (i1_{SD2}) of the second summing device SD2 is connected to a node 413 through a connection having the resistance R1. Also, the second input (i2_{SD2}) of the second summing device SD2 is connected to the node 413 through a connection having the resistance R2. The node 413 is connected to a positive input (+) of an amplifier 415. A negative input (−) of the amplifier 415 is connected to a reference ground potential. An output of the amplifier 415 is connected to the output (o1_{SD2}) of the second summing device SD2. Also, the node 413 is connected to the output (o1_{SD2}) of the second summing device SD2 through a connection that also has the resistance R1 and that bypasses the amplifier 415. In this manner, the voltage at the output (o1_{SD2}) of the second summing device SD2 is equal to a sum of the voltage V1 at the first input (i1_{SD2}) of the second summing device SD2 and a product of the voltage V2 at the second input (i2_{SD2}) of the second summing device SD2 and a ratio of the resistance R1 divided by the resistance R2, i.e., [V1+V2*(R1/R2)]=voltage at output o1_{SD2}.

It should be understood that the summing devices SD1 and SD2 of FIGS. 4A-4D are provided by way of example. In some embodiments, each of the first summing device SD1 and the second summing device SD2 is configured to generate and sum electrical currents based on the respective voltages received at the two inputs of the summing device and convert the summed electrical current into an output voltage of the summing device. In some embodiments, each of the first summing device SD1 and the second summing device SD2 is configured to sum voltages received at the two inputs of the summing device to generate the output voltage of the summing device.

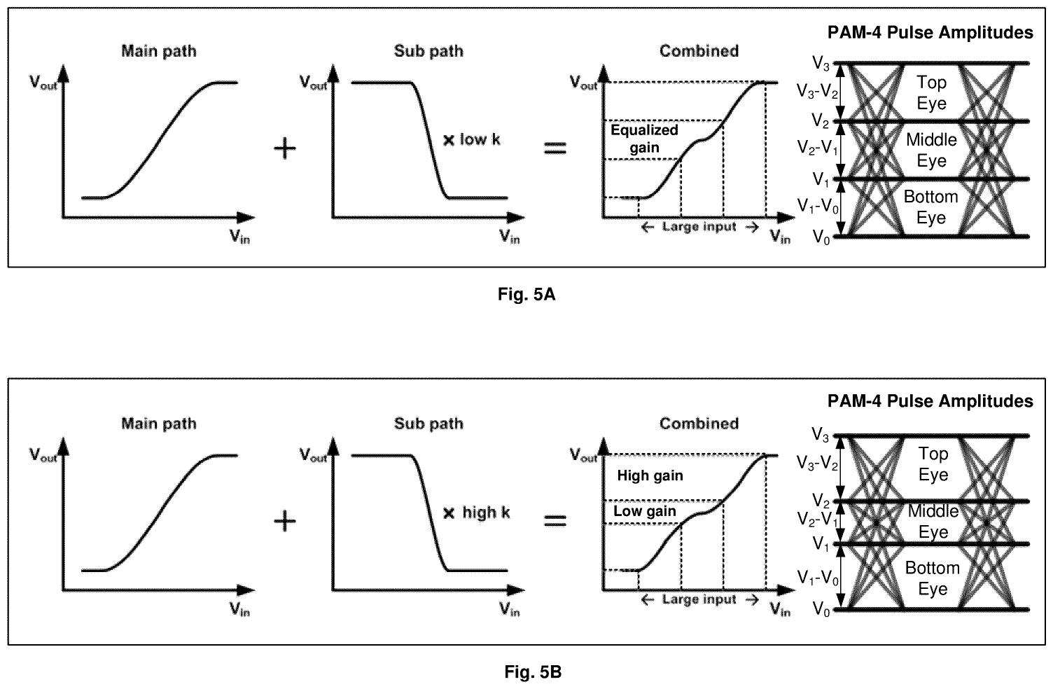

FIG. 5A shows the operating principle of the linearity control circuit 300 for a low coefficient (k) value, in accordance with some embodiments. FIG. 5B shows the operating principle of the linearity control circuit 300 for a high coefficient (k) value, in accordance with some embodiments.

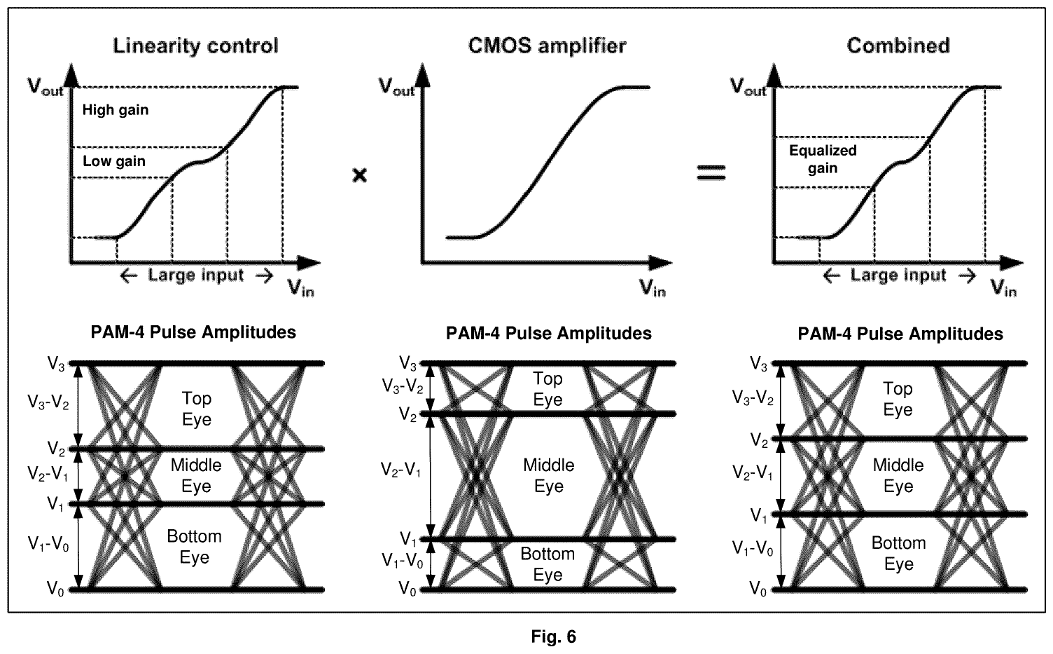

FIG. 6 shows how the linearity control circuit 300 operates to pre-distort the PAM-4 signal so as to tolerate/mitigate the linearity degradation that is caused by the CMOS repeater/amplifier, in accordance with some embodiments. FIG. 6 shows that the coefficient (k) is set to cause the linearity control circuit 300 to reduce the size of the middle eye (V2-V1) of the PAM-4 signal in order mitigate the increase in the size of the middle eye (V2-V1) of the PAM-4 signal as caused by the non-linearity of the CMOS repeater/amplifier. Because the middle eye (V2-V1) of the PAM-4 signal becomes larger as the signal propagates through the CMOS repeater/amplifier chain, such as shown in FIG. 2, the sizes of the top, middle, and bottom eyes of the PAM-4 signal can be substantially equalized at the output of the CMOS repeater/amplifier chain by using the linearity control circuit 300 to make the middle eye (V2-V1) of the PAM-4 signal smaller at the launch point of the PAM-4 signal into the CMOS repeater/amplifier. In this manner, the linearity control circuit 300 is used to tolerate/mitigate the non-linearity of the PAM-4 signal that is introduced by the CMOS repeater/amplifier. It should be understood that in various embodiments the linearity control circuit 300 can be implemented either before or after the CMOS repeater/amplifier chain within the electrical signal conveyance pathway.

In accordance with the foregoing, various embodiments are disclosed herein for a linearity control circuit that includes a first input terminal, a second input terminal, a first differential amplifier, a first weighting circuit, a second differential amplifier, a second weighting circuit, a first summing device, and a second summing device. The first differential amplifier has a first input connected to the second input terminal and a second input connected to the first input terminal. The first differential amplifier has a first output and a second output. The first weighting circuit has a first input connected to the first output of the first differential amplifier. The first weighting circuit has a second input connected to the second output of the first differential amplifier. The first weighting circuit has a first output and a second output. The first weighting circuit is configured to scale signals received at each of first and second inputs of the first weighting circuit by a first scaling coefficient to generate respective signals at the first and second outputs of the first weighting circuit.

The second differential amplifier has a first input connected to the first input terminal and a second input connected to the second input terminal. The second differential amplifier has a first output and a second output. The second weighting circuit has a first input connected to the first output of the second differential amplifier. The second weighting circuit has a second input connected to the second output of the second differential amplifier. The second weighting circuit has a first output and a second output. The second weighting circuit is configured to scale signals received at each of first and second inputs of the second weighting circuit by a second scaling coefficient to generate respective signals at the first and second outputs of the second weighting circuit.

The first summing device has a first input connected to the first output of the first weighting circuit. The first summing device has a second input connected to the first output of the second weighting circuit. The first summing device has an output that is a first output of the linearity control circuit. The second summing device has a first input connected to the second output of the first weighting circuit. The second summing device has a second input connected to the second output of the second weighting device. The second summing device has an output that is a second output of the linearity control circuit.

The first differential amplifier and the first weighting circuit form a main path. The second differential amplifier and the second weighting circuit form a sub path. The sub path has a flipped polarity relative to the main path. In some embodiments, the first input terminal is connected to receive a negative version of a given input signal, and the second input terminal is connected to receive a positive version of the given input signal.

In some embodiments, a gain of the second differential amplifier is higher than a gain of the first differential amplifier. In some embodiments, a gain of the second weighting circuit is scaled relative to a gain of the first weighting circuit by a ratio of the second scaling coefficient over the first scaling coefficient. In some embodiments, the first scaling coefficient and the second scaling coefficient are set to adjust a weight of the sub path relative to the main path. In some embodiments, the second scaling coefficient is less than the first scaling coefficient. In some embodiments, the first scaling coefficient is one. In some embodiments, a gain of the linearity control circuit is equal to a gain of the main path minus a gain of the sub path when the given input signal does not cause the sub path to saturate. Also, in these embodiments, the gain of the linearity control circuit is equal to the gain of the main path when the given input signal does cause the sub path to saturate. In some embodiments, the linearity control circuit provides an amount of gain reduction around a common mode voltage that is proportional to the second scaling coefficient. In some embodiments, the second scaling coefficient is set to substantially equalize a top eye, a middle eye, and a bottom eye of a PAM-4 signal transmission.

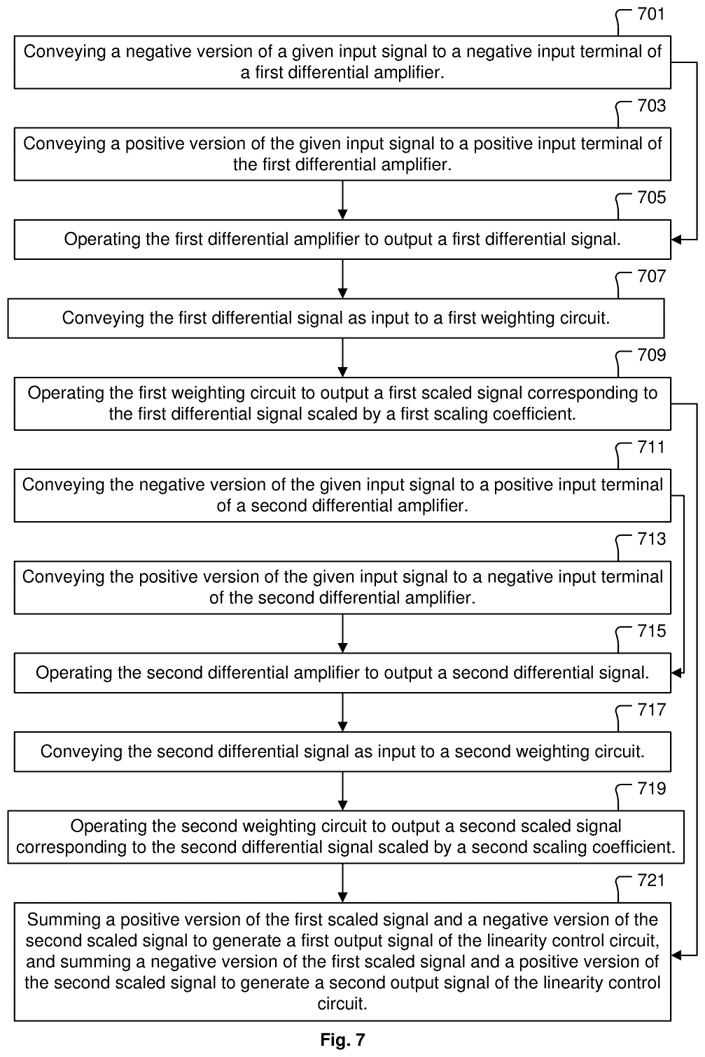

FIG. 7 shows a flowchart of a method for operating a linearity control circuit, in accordance with some embodiments. The method includes an operation 701 for conveying a negative version of a given input signal to a negative input terminal of a first differential amplifier. The method also includes an operation 703 for conveying a positive version of the given input signal to a positive input terminal of the first differential amplifier. The operations 701 and 703 are performed simultaneously. The method also includes an operation 705 for operating the first differential amplifier to output a first differential signal. The method also includes an operation 707 for conveying the first differential signal as input to a first weighting circuit. The method also includes an operation 709 for operating the first weighting circuit to output a first scaled signal corresponding to the first differential signal scaled by a first scaling coefficient.

The method also includes an operation 711 for conveying the negative version of the given input signal to a positive input terminal of a second differential amplifier. The method also includes an operation 713 for conveying the positive version of the given input signal to a negative input terminal of the second differential amplifier. The operations 711 and 713 are performed simultaneously. The method also includes an operation 715 for operating the second differential amplifier to output a second differential signal. The method also includes an operation 717 for conveying the second differential signal as input to a second weighting circuit. The method also includes an operation 719 for operating the second weighting circuit to output a second scaled signal corresponding to the second differential signal scaled by a second scaling coefficient. The set of operations 701 through 709 are performed simultaneously with the set of operations 711 through 719. The method also includes an operation 721 for summing a positive version of the first scaled signal and a negative version of the second scaled signal to generate a first output signal of the linearity control circuit, and summing a negative version of the first scaled signal and a positive version of the second scaled signal to generate a second output signal of the linearity control circuit.

The first differential amplifier and the first operational amplifier form a main path, and the second differential amplifier and the second operational amplifier form a sub path, where the sub path has a flipped polarity relative to the main path. In some embodiments, the method includes setting a gain of the second differential amplifier higher than a gain of the first differential amplifier. In some embodiments, the method includes setting the second scaling coefficient to be less than the first scaling coefficient. In some embodiments, the method includes setting the first scaling coefficient and the second scaling coefficient to adjust a weight of the sub path relative to the main path. In some embodiments, the first scaling coefficient is one. In some embodiments, a gain of the linearity control circuit is equal to a gain of the main path minus a gain of the sub path when the given input signal does not cause the sub path to saturate. Also, in these embodiments, the gain of the linearity control circuit is equal to the gain of the main path when the given input signal does cause the sub path to saturate.

In some embodiments, the method includes setting the second scaling coefficient to substantially equalize a top eye, a middle eye, and a bottom eye of a PAM-4 signal transmission. In some embodiments, the method includes setting the second scaling coefficient to reduce a gain for a middle eye of a PAM-4 signal transmission, while maintaining a substantially same gain for each of a top eye and a bottom eye of the PAM-4 signal transmission. In some embodiments, the method includes setting the second scaling coefficient to pre-distort one or more of a top eye, a middle eye, and a bottom eye of a PAM-4 signal transmission to mitigate linearity degradation caused by a repeater/amplifier chain.

The foregoing description of the embodiments has been provided for purposes of illustration and description, and is not intended to be exhaustive or limiting. Individual elements or features of a particular embodiment are generally not limited to that particular embodiment, but, where applicable, are interchangeable and can be used in a selected embodiment, even if not specifically shown or described. In this manner, one or more features from one or more embodiments disclosed herein can be combined with one or more features from one or more other embodiments disclosed herein to form another embodiment that is not explicitly disclosed herein, but rather that is implicitly disclosed herein. This other embodiment may also be varied in many ways. Such embodiment variations are not to be regarded as a departure from the disclosure herein, and all such embodiment variations and modifications are intended to be included within the scope of the disclosure provided herein.

Although some method operations may be described in a specific order herein, it should be understood that other operations may be performed in between method operations, and/or method operations may be adjusted so that they occur at slightly different times or simultaneously, or may be distributed in a system which allows the occurrence of the processing operations at various intervals associated with the processing, as long as the processing of the method operations are performed in a manner that provides for successful implementation of the method.

Although the foregoing embodiments have been described in some detail for purposes of clarity of understanding, it will be apparent that certain changes and modifications can be practiced within the scope of the appended claims. Accordingly, the embodiments disclosed herein are to be considered as illustrative and not restrictive, and are therefore not to be limited to just the details given herein, but may be modified within the scope and equivalents of the appended claims.

What is claimed is:

1. A linearity control circuit, comprising:
a first input terminal;
a second input terminal;
a first differential amplifier having a first input connected to the second input terminal and a second input connected to the first input terminal, the first differential amplifier having a first output and a second output;
a first weighting circuit having a first input connected to the first output of the first differential amplifier, the first weighting circuit having a second input connected to the second output of the first differential amplifier, the first weighting circuit having a first output and a second output, the first weighting circuit configured to scale signals received at each of first and second inputs of the first weighting circuit by a first scaling coefficient to generate respective signals at the first and second outputs of the first weighting circuit;
a second differential amplifier having a first input connected to the first input terminal and a second input connected to the second input terminal, the second differential amplifier having a first output and a second output;
a second weighting circuit having a first input connected to the first output of the second differential amplifier, the second weighting circuit having a second input connected to the second output of the second differential amplifier, the second weighting circuit having a first output and a second output, the second weighting circuit configured to scale signals received at each of first and second inputs of the second weighting circuit by a second scaling coefficient to generate respective signals at the first and second outputs of the second weighting circuit;
a first summing device having a first input connected to the first output of the first weighting circuit, the first summing device having a second input connected to the first output of the second weighting device, the first summing device having an output that is a first output of the linearity control circuit; and
a second summing device having a first input connected to the second output of the first weighting circuit, the second summing device having a second input connected to the second output of the second weighting device, the second summing device having an output that is a second output of the linearity control circuit.

2. The linearity control circuit as recited in claim 1, wherein the first input terminal is connected to receive a negative version of a given input signal, and wherein the second input terminal is connected to receive a positive version of the given input signal.

3. The linearity control circuit as recited in claim 2, wherein the first differential amplifier and the first weighting circuit form a main path, wherein the second differential amplifier and the second weighting circuit form a sub path, and wherein the sub path has a flipped polarity relative to the main path.

4. The linearity control circuit as recited in claim 3, wherein a gain of the second differential amplifier is higher than a gain of the first differential amplifier.

5. The linearity control circuit as recited in claim 4, wherein the second scaling coefficient is less than the first scaling coefficient.

6. The linearity control circuit as recited in claim 5, wherein the first scaling coefficient and the second scaling coefficient are set to adjust a weight of the sub path relative to the main path.

7. The linearity control circuit as recited in claim 6, wherein the first scaling coefficient is one.

8. The linearity control circuit as recited in claim 7, wherein a gain of the linearity control circuit is equal to a gain of the main path minus a gain of the sub path when the given input signal does not cause the sub path to saturate, and wherein the gain of the linearity control circuit is equal to the gain of the main path when the given input signal does cause the sub path to saturate.

9. The linearity control circuit as recited in claim 7, wherein the second scaling coefficient is set to substantially equalize a top eye, a middle eye, and a bottom eye of a PAM-4 signal transmission.

10. The linearity control circuit as recited in claim 7, wherein the linearity control circuit provides an amount of gain reduction around a common mode voltage that is proportional to the second scaling coefficient.

11. A method for operating a linearity control circuit, comprising:
conveying a negative version of a given input signal to a negative input terminal of a first differential amplifier;
conveying a positive version of the given input signal to a positive input terminal of the first differential amplifier;
operating the first differential amplifier to output a first differential signal;
conveying the first differential signal as input to a first weighting circuit;
operating the first weighting circuit to output a first scaled signal corresponding to the first differential signal scaled by a first scaling coefficient;
conveying the negative version of the given input signal to a positive input terminal of a second differential amplifier;
conveying the positive version of the given input signal to a negative input terminal of the second differential amplifier;
operating the second differential amplifier to output a second differential signal;
conveying the second differential signal as input to a second weighting circuit;
operating the second weighting circuit to output a second scaled signal corresponding to the second differential signal scaled by a second scaling coefficient;
summing a positive version of the first scaled signal and a negative version of the second scaled signal to generate a first output signal of the linearity control circuit; and
summing a negative version of the first scaled signal and a positive version of the second scaled signal to generate a second output signal of the linearity control circuit.

12. The method as recited in claim 11, wherein the first differential amplifier and the first weighting circuit form a main path, wherein the second differential amplifier and the second weighting circuit form a sub path, and wherein the sub path has a flipped polarity relative to the main path.

13. The method as recited in claim 12, further comprising:
setting a gain of the second differential amplifier higher than a gain of the first differential amplifier.

14. The method as recited in claim 13, further comprising:
setting the second scaling coefficient to be less than the first scaling coefficient.

15. The method as recited in claim 14, further comprising:
setting the first scaling coefficient and the second scaling coefficient to adjust a weight of the sub path relative to the main path.

16. The method as recited in claim 15, wherein the first scaling coefficient is one.

17. The method as recited in claim 16, wherein a gain of the linearity control circuit is equal to a gain of the main path minus a gain of the sub path when the given input signal does not cause the sub path to saturate, and wherein the gain of the linearity control circuit is equal to the gain of the main path when the given input signal does cause the sub path to saturate.

18. The method as recited in claim 16, further comprising:
setting the second scaling coefficient to substantially equalize a top eye, a middle eye, and a bottom eye of a PAM-4 signal transmission.

19. The method as recited in claim 16, further comprising:
setting the second scaling coefficient to reduce a gain for a middle eye of a PAM-4 signal transmission, while maintaining a substantially same gain for each of a top eye and a bottom eye of the PAM-4 signal transmission.

20. The method as recited in claim 16, further comprising:
setting the second scaling coefficient to pre-distort one or more of a top eye, a middle eye, and a bottom eye of a PAM-4 signal transmission to mitigate linearity degradation caused by a repeater/amplifier chain.
